(19) United States
(12) Patent Application Publication
(10) Pub. No.: US 2026/0040536 A1
(43) Pub. Date: Feb. 5, 2026

(54) MEMORY DEVICE HAVING IN-TIER ACCESS LINE DRIVERS

(71) Applicant: Micron Technology, Inc., Boise, ID (US)

(72) Inventors: Eric S. Carman, San Francisco, CA (US); Kamal M. Karda, Boise, ID (US); Duane R. Mills, Shingle Springs, CA (US)

(21) Appl. No.: 18/791,206

(22) Filed: Jul. 31, 2024

(51) Int. Cl. H10B 12/00; G11C 11/408

(52) U.S. Cl. CPC H10B 12/50; G11C 11/4085; H10B 12/30

(57) ABSTRACT

A variety of applications can include an apparatus having a three-dimensional (3D) memory device with sub-access line drivers to access lines embedded in a memory array of the 3D memory device. A sub-access line driver to an access line to a tier of memory cells of the memory array can include two transistors coupled to each other and the access line. A first transistor of the two transistors can be coupled at one end of the access line and the second transistor of the two transistors can be coupled at the other end of the access.

### FIELD OF THE DISCLOSURE

Embodiments of the disclosure relate generally to electronic devices and systems, and more specifically, to memory devices, components of memory devices, and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 represents two memory arrays of a three-dimensional dynamic random-access memory device, where the memory arrays have tiers of memory cells.

FIG. 2 represents an example sub-access line driver that can be embedded in an array of memory cells of a three-dimensional memory device, where the array is arranged in tiers of memory cells, in accordance with various embodiments.

FIG. 3 illustrates an example of a three-dimensional dynamic random-access memory device having an array of memory cells arranged in tiers of memory cells, in accordance with various embodiments.

FIG. 4 is a representation of an example three-dimensional dynamic random-access memory device similar to the three-dimensional dynamic random-access memory device of FIG. 3, in accordance with various embodiments.

FIG. 5 represents an example three-dimensional dynamic random-access memory device having an arrangement of memory arrays of memory cells employing the architecture of the three-dimensional dynamic random-access memory device of FIG. 3, in accordance with various embodiments.

FIG. 6 is a representation of an example three-dimensional dynamic random-access memory device having an arrangement of patches of memory cells employing features of an architecture similar to the architecture of the three-dimensional dynamic random-access memory device of FIG. 3, in accordance with various embodiments.

FIG. 7 is a representation of states of an access line of a three-dimensional memory device from inputs to a sub-access line driver to the access line, with the sub-access line driver structured as the example sub-access line driver of FIG. 2, in accordance with various embodiments.

FIG. 8 is a flow diagram of features of an example method of forming a memory device, in accordance with various embodiments.

FIG. 9 is a flow diagram of features of an example method of operating a memory device, in accordance with various embodiments.

FIG. 10 is a block diagram illustrating an example of a machine upon which one or more embodiments of one or more memory components may be implemented, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

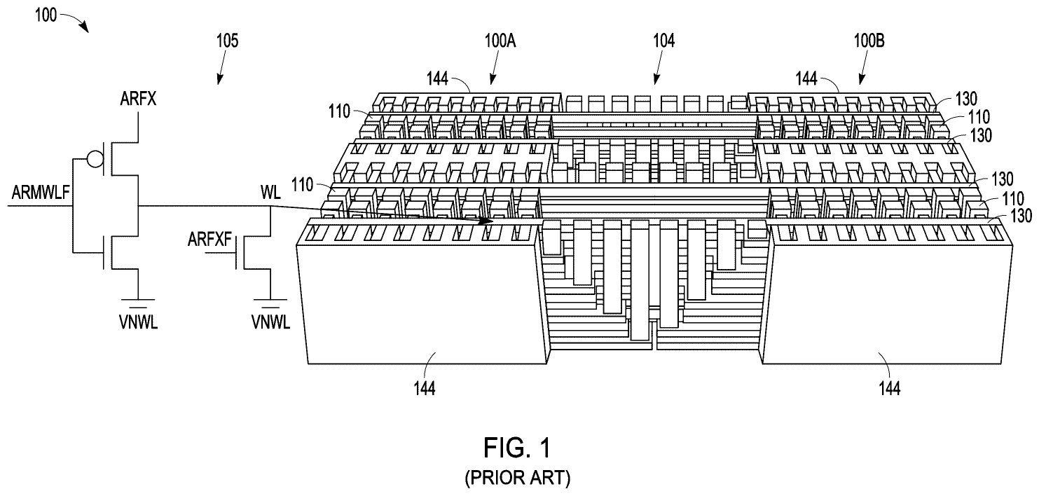

FIG. 1 represents a memory array 100A and memory array 100B of a current three-dimensional (3D) DRAM device 100, where memory array 100A and memory array 100B have tiers of memory cells. 3D DRAM device 100 includes access lines (WLs) 130, for example word lines, to memory cells in a first tier of memory cells for both memory array 100A and memory array 100B. WLs 130 are coupled to access transistors of the memory cells. Memory array 100A and memory array 100B include WLs shared by both memory arrays in the tiers of these memory arrays. Each of memory array 100A and memory array 100B independently include local digit lines (DLs). In addition, each of memory array 100A and memory array 100B independently include plates 144 coupled to capacitors of the memory cells of the respective memory array, where the capacitors are coupled to access transistors for the memory cells, the WLs local digit lines (DLs). A staircase of contacts 104 is disposed between memory array 100A and memory array 100B to provide signals to WLs 130 and the WLs of the tiers of the two memory arrays. Each contact of the staircase of contacts 104 occupies an area on a step of the staircase, referred to as tread width. Signals to each WL is provided by a sub-access line driver (SWD) corresponding to the WL. A SWD is transistor circuitry immediately connected to a WL.

FIG. 1 also represents a SWD 105 that is coupled to one WL of the first tier of memory array A and memory array B. The physical structure of SWD 105 is not shown, since SWD 105 is not physically integrated within memory array A and memory array B. SWD 105 can be located on a die separate from the die on which memory array A and memory array B are structured. For instance, SWD 105 can be on a wafer that is combined with the wafer containing memory array A and memory array B. SWD 105 is a three-transistor structure that includes a p-type metal-oxide-semiconductor field-effect (PMOS) transistor and a n-type metal-oxide semiconductor field-effect (NMOS) transistor coupled together with an output coupled to a second NMOS and to the WL. An input signal ARMWLF to the PMOS-NMOS combination directs a signal ARFX to the output or a constant reference voltage VNWL to the output. An input signal ARFXF is used to bias deselected WL at VNWL. To increase density of 3D DRAM device 100, enhancements to design of the memory arrays and staircases of contacts of 3D DRAM device 100 can be implemented.

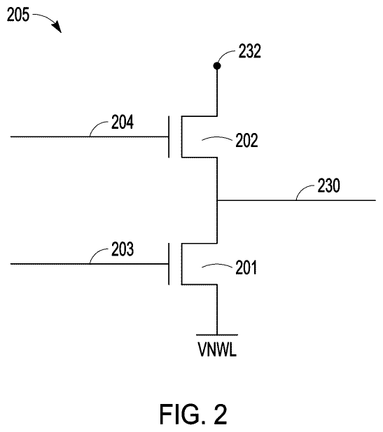

FIG. 2 represents an embodiment of an example SWD 205 that can be embedded in an array of memory cells of a 3D memory device, where the array is arranged in tiers of memory cells. Each memory cell can be structured with an access transistor and a storage component. SWD 205 comprises a transistor 202 coupled to another transistor 201 with an output line 230 at the coupling of transistor 202 to transistor 201. At the coupling, output line 230 is coupled to the source of transistor 202 and the drain of transistor 201. Transistor 201 and transistor 202 can be NMOS transistors. Transistor 201 and transistor 202 can be thin film transistors (TFTs).

Embedded in a memory array, the output line 230 of SWD 205 can be an access line (WL) to one or more memory cells. In an arrangement of transistors 201 and 202 with output line 230 being an WL, transistor 201 can be coupled to output line 230 at a first end of output line 230 and transistor 202 can be coupled to output line 230. With output line 230 being a WL, such as a conductive trace for activating an access transistor, transistor 201 and transistor 202 can be at opposite ends of the WL. The voltage on output line 230 can be controlled by a control voltage applied on input line 204 applied on the input line to the gate of transistor 202 and a control voltage applied on input line 203 to the gate of transistor 201, with respect to a signal, referred to herein as ARFX, applied at node 232 and a reference voltage at node VNWL. The voltage applied to input line 204 to the gate of transistor 202 is herein referred to ARMWL, which is a signal to pull up the gate of transistor 202 to pull WL to ARFX. The voltage applied to input line 203 to the gate of transistor 201 is herein referred to ARMWLF, which is a signal to pull down the gate of transistor 201 to bias WL at VNWL. The reference voltage at node VNWL can be a constant voltage operatively provided to SWD 205 with the signal at node 232 being a signal to operatively pass through transistor 202 to output line 230. Transistor 202 with its gate coupled to input line 204 can be arranged as a pass gate to output line 230 and transistor 201 with its gate coupled to input line 203 can be arranged as an idle gate to output line 230. The idle gate can provide a voltage level to a WL that keeps a memory cell from being accessed.

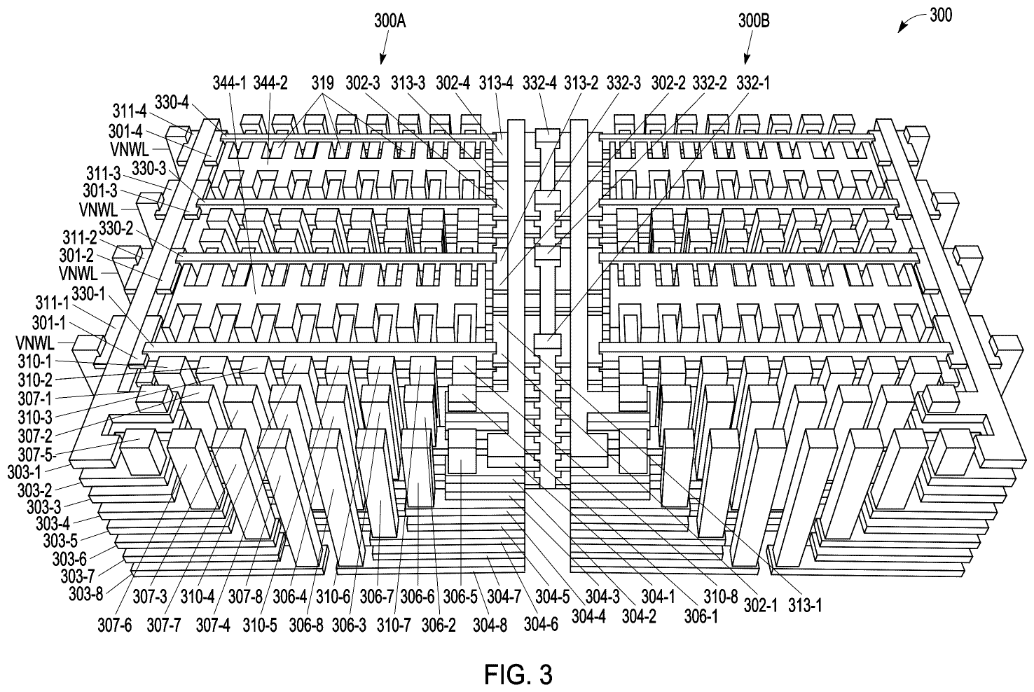

FIG. 3 illustrates an embodiment of an example 3D DRAM device 300 having an array of memory cells arranged in tiers of memory cells, where a memory cell includes an access transistor and a capacitor constructed as a storage component. 3D DRAM device 300 can include WLs and data lines coupled to access transistors of memory cells at each tier of the array. A SWD can be coupled to an WL, where the WL can be coupled to one or more access transistors of the array on a tier of the array.

As shown in FIG. 3, 3D DRAM device 300 can comprise two arrays 300A and 300B of memory cells. For case of discussion, reference labels are shown for array 300A with array 300B constructed in a similar manner though in the opposite direction from array 300A. Though eight tiers are shown, a 3D memory device similar to 3D DRAM device 300 can have more or fewer than eight tiers. Each tier can be structured in the same manner with a staircase of contacts to couple to memory cells on the tiers. On the first tier, array 300A includes WLs 330-1, 330-2, 330-3, and 330-4. A first SWD is embedded in the first tier and is coupled to WL 330-1. A second SWD is embedded in the first tier and is coupled to WL 330-2. A third SWD is embedded in the first tier and is coupled to WL 330-3. A fourth SWD is embedded in the first tier and is coupled to WL 330-4. The SWDs can be realized in a manner similar to SWD 205 of FIG. 2.

The first SWD can include a transistor 301-1 and a transistor 302-1 coupled together by WL 330-1. Transistors 301-1 and 302-1 can be, but are not limited to, TFTs. Transistor 301-1 can be coupled to a node VNWL and transistor 302-1 can be coupled to a node 332-1. Node VNWL can be arranged to provide a reference voltage that can be a constant voltage. Transistor 302-1 can be coupled to a node 332-1 to provide a signal to operatively pass through transistor 302-1 to WL 330-1, in conjunction with transistor 301-1. Node VNWL and node 332-1 can be constructed as column structures.

The second SWD can include a transistor 301-2 and a transistor 302-2 coupled together by WL 330-2. Transistors 301-2 and 302-2 can be, but are not limited to, TFTs. Transistor 301-2 can be coupled to a node VNWL and transistor 302-2 can be coupled to a node 332-2. Node VNWL can be arranged to provide a reference voltage that can be a constant voltage. Transistor 302-2 can be coupled to a node 332-2 to provide a signal to operatively pass through transistor 302-2 to WL 330-2, in conjunction with transistor 301-2. Node VNWL and node 332-2 can be constructed as column structures.

The third SWD can include a transistor 301-3 and a transistor 302-3 coupled together by WL 330-3. Transistors 301-3 and 302-3 can be, but are not limited to, TFTs. Transistor 301-3 can be coupled to a node VNWL and transistor 302-3 can be coupled to a node 332-3. Node VNWL can be arranged to provide a reference voltage that can be a constant voltage. Transistor 302-3 can be coupled to a node 332-3 to provide a signal to operatively pass through transistor 302-3 to WL 330-3, in conjunction with transistor 301-3. Node VNWL and node 332-3 can be constructed as column structures.

The fourth SWD can include a transistor 301-4 and a transistor 302-4 coupled together by WL 330-4. Transistors 301-4 and 302-4 can be, but are not limited to, TFTs. Transistor 301-4 can be coupled to a node VNWL and transistor 302-4 can be coupled to a node 332-4. Node VNWL can be arranged to provide a reference voltage that can be a constant voltage. Transistor 302-4 can be coupled to a node 332-4 to provide a signal to operatively pass through transistor 302-4 to WL 330-4, in conjunction with transistor 301-4. Node VNWL and node 332-4 can be constructed as column structures.

Electrical coupling to components of the SWDs on the eight tiers can be provided by a staircase having two steps for each tier of array 300A. For example, one step 303-1 of the first tier has a conductive extension that provides a gate or is on and contacting gates to transistors 301-1, 301-2, 301-3, and 301-4 and is located on gate dielectrics 311-1, 311-2, 311-3, and 311-4. The second step 304-1 of the first tier provides has a conductive extension that provides a gate or is on and contacting gates to transistors 302-1, 302-2, 302-3, and 302-4 and is located on gate dielectrics 313-1, 313-2, 313-3, and 313-4. The extensions of steps 303-1 and steps 304-1 can run in a direction perpendicular to the access lines of the first tier of array 300A. Steps 303-2 and 304-2, steps 303-3 and 304-3, steps 303-4 and 304-4, steps 303-5 and 304-5, steps 303-6 and 304-6, steps 303-7 and 304-7, and steps 303-8 and 304-8 can be constructed as pairs in the same manner as steps 303-1 and 304-1 with respect to the SWDs of the respective tiers. Instead of having contact for one SWD for each access line in a tier such as in 3D DRAM device 100 of FIG. 1, this arrangement provides contact for a set of SWDs to multiple access lines of the tier.

Vertical contacts can be arranged in two rows on the steps to provide voltages to the SWDs on the different tiers, with the voltages provided from other portions of 3D memory device 300. Vertical contacts 307-1, 307-2, 307-3, 307-4, 306-4, 306-3, 306-2, and 306-1 in one row are placed on staircase steps 303-1, 303-3, 303-5, 303-7, 304-7, 304-5, 304-3, and 304-1, respectively. Vertical contacts 307-5, 307-6, 307-7, 307-8, 306-8, 306-7, 306-6, and 306-5 in the other row are placed on staircase steps 303-2, 303-4, 303-6, 303-8, 304-8, 304-6, 304-4, and 304-2, respectively.

Array 300A can include vertically arranged local digit lines (DLs) to the memory cells of the array 300A, with WLs to memory cells arranged horizontally in the tiers of array 300A. The vertically arranged local DLs can be disposed within a volume of array 300A. Local DLs 310-1 . . . 310-8 are coupled to access transistors to which WL 330-1 is coupled in the first tier. Local DL 310-1 is coupled to a first access transistor of the first tier to which WL 330-1 is coupled and to an associated capacitor that is coupled to plate 344-1. Local DL 310-2 is coupled to a second access transistor of the first tier to which WL 330-1 is coupled and to an associated capacitor that is coupled to plate 344-1. Local DL 310-3 is coupled to a third access transistor of the first tier to which WL 330-1 is coupled and to an associated capacitor that is coupled to plate 344-1. Local DL 310-4 is coupled to a fourth access transistor of the first tier to which WL 330-1 is coupled and to an associated capacitor that is coupled to plate 344-1. Local DLs 310-5-210-8 are coupled in the same to fifth through eight access transistors of the first tier to which WL 330-1 is coupled and to associated capacitors that are coupled to plate 344-1. Each of local DLs 310-1 . . . 310-8 is coupled in a vertical direction to multiple access transistors in array 300A, with each access transistor in the vertical direction on a different one of the eight tiers. Each of WLs 330-2, 330-3, and 330-4 can be constructed with respective DLs, access transistors, and plates to capacitors in a manner similar to WL 330-1. A plate 344-2 can be used with respect to WLs 330-3 and 330-4 in the same manner as plate 344-1 is used with respect to WLs 330-1 and 330-2. The access transistors and associated capacitors are below the top surface of array 300A shown and are separated by dielectrics such as dielectric 319 that electrically isolates components of array 300A.

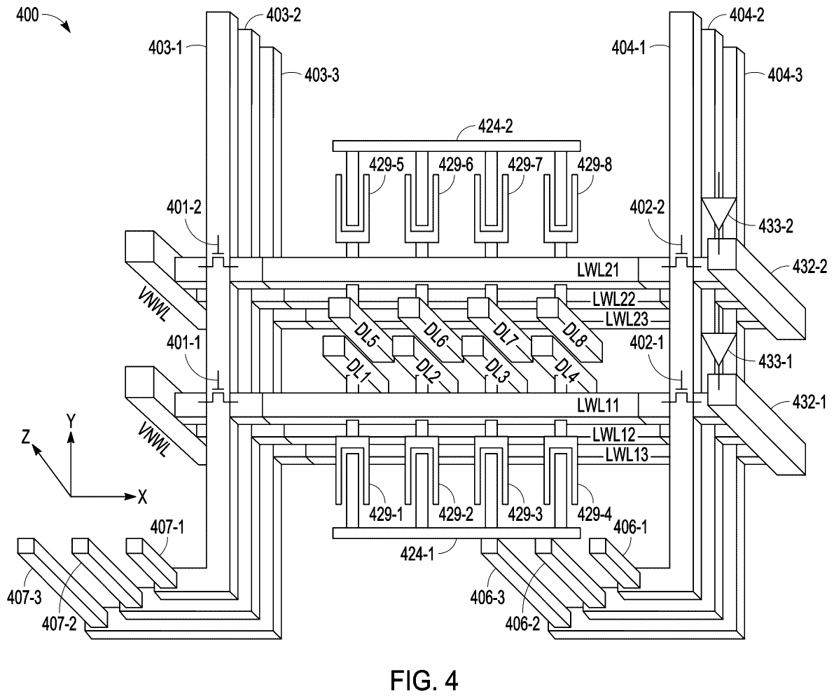

FIG. 4 is a representation of an embodiment of an example 3D DRAM device 400 similar to 3D DRAM device 300 of FIG. 3. Various components and electrical isolation of the components from each other are not shown to focus on the relationship of WLs, local DLs, SWDs, staircases of contacts to the SWDs. In FIG. 4, 3D DRAM device 400 is shown to have three tiers of memory cells, where each memory cell is structured as an access transistor and a capacitor, with local WLs (LWLs) coupled to the access transistors. Access transistors of 3D DRAM device 300 are not shown, as they are under WLs and have active areas coupled to a DL and to a capacitor. A first LWL 11 on a first tier is coupled to an access transistor that is coupled to DL1 and a capacitor 429-1, an access transistor that is coupled to DL2 and capacitor 429-2, an access transistor that is coupled to DL3 and capacitor 429-3, and an access transistor that is coupled to DL4 and capacitor 429-4. First LWL 11 is on the first tier above a first LWL 12 on the second tier that is above a first LWL 13 on the third tier. LWL 12 and LWL 13 are configured with respect to DLs and capacitors in the same manner as LWL 11. Capacitors 429-1 . . . 429-4 and capacitors associated with LWL 12 and LWL 13 are coupled to a plate 424-1.

A second LWL 21 on a first tier is coupled to an access transistor that is coupled to DL5 and a capacitor 429-5, an access transistor that is coupled to DL6 and capacitor 429-6, an access transistor that is coupled to DL7 and capacitor 429-7, and an access transistor that is coupled to DL8 and capacitor 429-8. Second LWL 21 is on a first tier above a second LWL 22 on a second tier that is above a second LWL 23 on a third tier. LWL 12 and LWL 13 are configured with respect to DLs and capacitors in the same manner as LWL 11. Capacitors 429-5 . . . 429-8 and capacitors associated with LWL 22 and LWL 23 are coupled to a plate 424-2.

3D DRAM device 400 includes an SWD to each WL on each tier with the SWD having a pass transistor and an idle transistor, with the WL coupled to pass transistor at one end of WL and coupled to an idle transistor at the opposite end of the WL. Each pass transistor is coupled to a pass staircase and each idle transistor is coupled to an idle staircase. A first SWD on the first tier includes an idle transistor 401-1 and a pass transistor 402-1 coupled to each other by LWL 11. Idle transistor 401-1 on the first tier has a source coupled to a VNWL node and a drain coupled to LWL 11, with an extension of step 403-1 arranged as a gate to idle transistor 401-1 or as a contact to the gate of idle transistor 401-1. Step 403-1 includes a platform connected to the extension, where the platform is constructed to hold a vertical contact 407-1. Pass transistor 402-1 on the first tier has a source coupled to LWL 11 and a drain coupled to a signal node 432-1, with an extension of step 403-1 arranged as a gate to idle transistor 401-1 or as a contact to gate of idle transistor 401-1. An external signal source 433-1 is coupled to signal node 432-1 that is constructed as a vertical node. Step 404-1 includes a platform connected to the extension, where the platform is constructed to hold a vertical contact 406-1.

A second SWD on the first tier includes an idle transistor 401-2 and a pass transistor 402-2 coupled to each other by LWL 21. Idle transistor 402-1 on the first tier has a source coupled to a VNWL node and a drain coupled to LWL 21, with extension of step 403-1 arranged as a gate to idle transistor 402-2 or as a contact to the gate of idle transistor 402-2. Pass transistor 402-2 on the first tier has a source coupled to LWL 21 and a drain coupled to a signal node 432-2, with an extension of step 404-1 arranged as a gate to pass transistor 402-2 or as a contact to gate of pass transistor 402-2. An external signal source 433-2 is coupled to signal node 432-2 that is constructed as a vertical node. Step 404-1 includes a platform connected to the extension, where the platform is constructed to hold a vertical contact 406-1.

Tier 2 includes SWDs coupled to a step 403-2 of the idle staircase with a contact 407-2 on a platform of step 403-2 and to a step 404-2 of the pass staircase with a contact 406-2 on a platform of step 404-2. Tier 3 includes SWDs coupled to a step 403-3 of the idle staircase with a contact 407-3 on a platform of step 403-3 and to a step 404-3 of the idle staircase with a contact 406-2 on a platform of step 404-2. The SWDs of tiers 2 and 3 are structured in the same manner as the SWDs of tier 1.

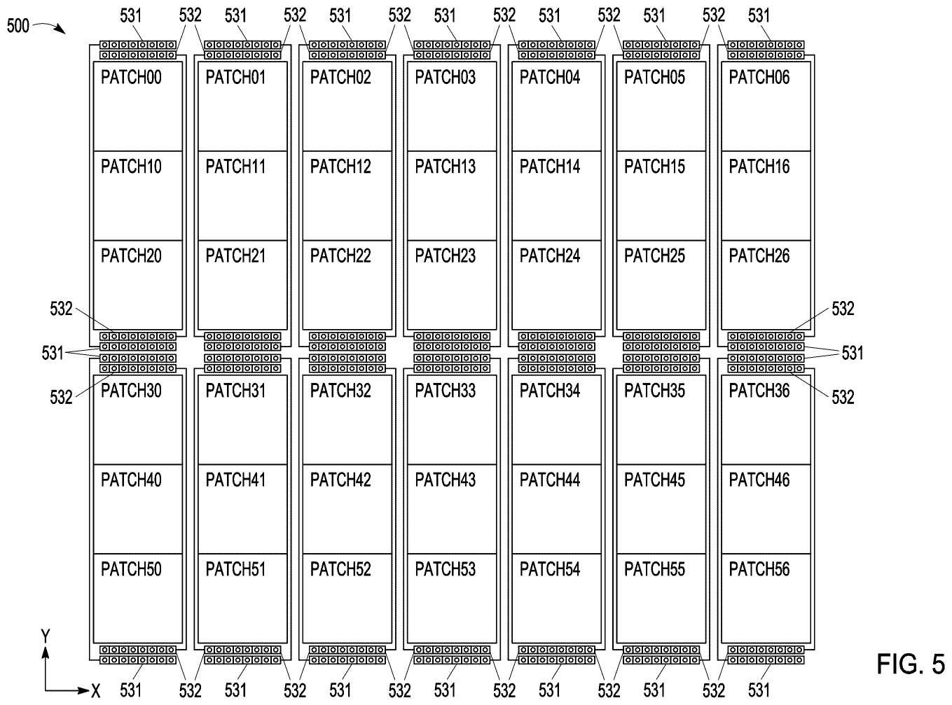

FIG. 5 represents an embodiment of an example 3D DRAM device having an arrangement of memory arrays of memory cells employing the architecture of 3D DRAM device 300 of FIG. 3. The memory arrays, referred to as patches, can be grouped as a collection of patches arranged as banks. In this example, there are patch00, patch01 . . . patch26 and patch30, patch31 . . . patch56 arranged with three patches coupled to two pass staircases 532 having contact columns (shown as dots) and to two idle staircases 531 having contact columns (shown as dots). Contacts on pass staircases 532 run in the x-direction parallel to the WLs of the three patches with extensions that run perpendicular to the WLs on one side of the three patches. Contacts on idle staircases 531 run in the x-direction parallel to the WLs of the three patches with extensions that run perpendicular to the WLs on the side of the three patches opposite the extensions of pass staircases 532.

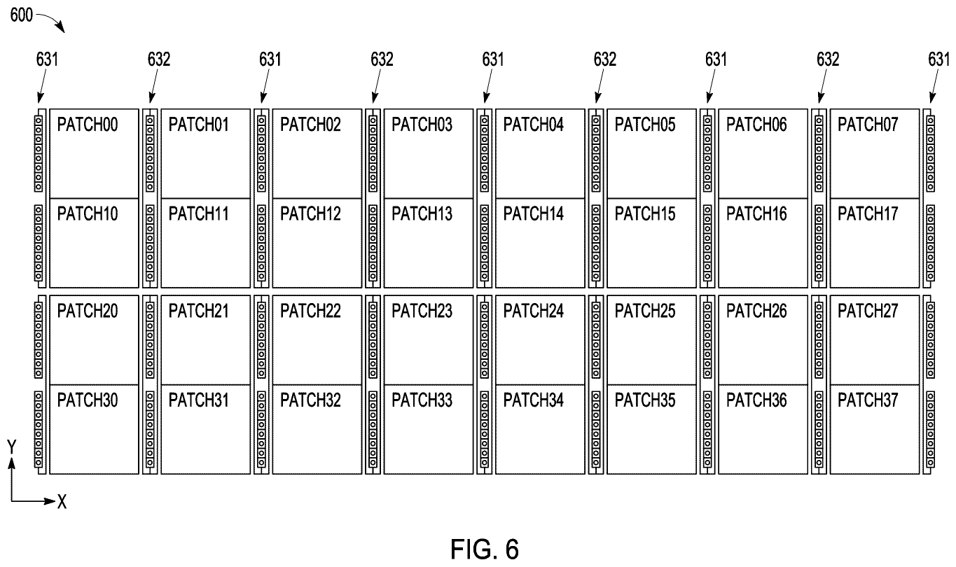

FIG. 6 is a representation of an embodiment of an example a 3D DRAM device having an arrangement of patches of memory cells employing features of an architecture similar to the architecture of 3D DRAM device 300 of FIG. 3. The patches are grouped as a collection of two patches running in the y-direction. In this example, there are patch00, patch01 . . . patch37. The collection of two patches is arranged coupled to two idle staircases 631 having contact columns (shown as dots) on one side of the collection of two patches running in the y-direction and to two pass staircases 632 having contact columns (shown as dots) on the other side of the collection of the two patched running in the y-direction. Contacts on pass staircase 632 run perpendicular to the WLs of the two patches with extensions that run perpendicular to the WLs on one side of the two patches. Contacts on idle staircase 631 run perpendicular to the WLs of the two patches with extensions that also run perpendicular to the WLs on the side of the two patches opposite the extensions of pass staircase 632.

The structures of 3D DRAM device 300 of FIG. 3, arrangement of patches of FIG. 5 with staircases in the x-direction, and arrangement of patches of FIG. 6 with staircases in the y-direction can provide relaxed staircase tread width as compared to the tread width of the contacts of the staircase of 3D DRAM device 100 of FIG. 1 that are between memory arrays in the x-direction. The staircase of 3D DRAM device 300 can be realized as two rows, reducing the length of the staircase as compared to the single row of the staircase of 3D DRAM device 100. The reduced length can be translated to the relaxed staircase tread width. Additionally, memory cell density of the architecture of 3D DRAM device 300 can be increased by up to 16 to 20% as compared to an architecture similar to 3D DRAM device 100. Also, the SWD structure of SWD 205 of FIG. 2 using two NMOS transistor compared to the SWD structure of SWD 105 of FIG. 1 using a PMOS transistor with two NMOs transistors can significantly improve power usage. Use of a NMOS transistor instead of a PMOS transistor can reduce gate-induced drain leakage (GIDL) during idle of access transistors controlled by a SWD.

Fabrication of 3D DRAM devices with SWDs embedded with WLs in memory arrays may use one or two additional masks per tier as compared to 3D DRAM devices without the embedded SWDs. Additionally, SWDs embedded with WLs may use voltage pumps that are at a higher voltage than voltage pumps of 3D DRAM devices without the embedded SWDs. High voltage (HV) devices as used in control circuits of the 3D DRAM device may be used to drive the signals to the pass transistors, for example signal sources 433-1 and 433-2.

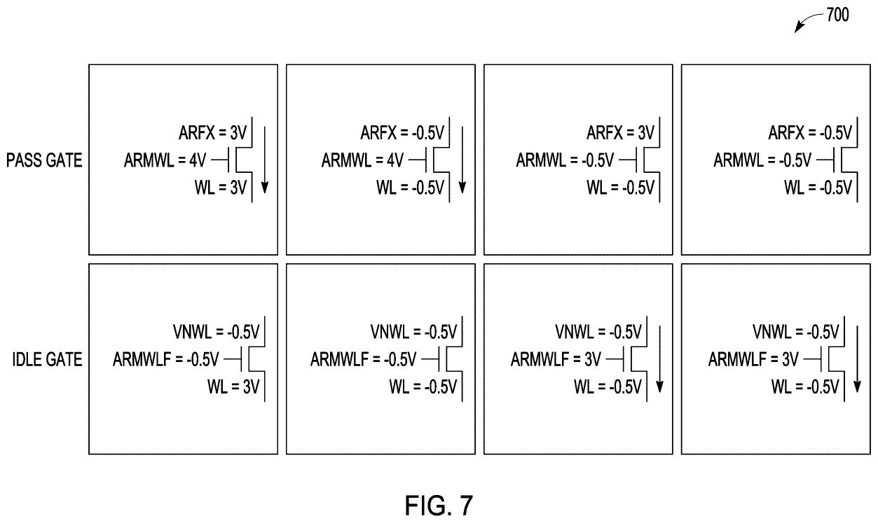

FIG. 7 is a representation 700 of states of a WL of a 3D memory device from inputs to a SWD to the WL, with the SWD structured as example SWD 205 of FIG. 2. A signal ARMWL can be applied to gate input 204 of transistor 202 arranged as a pass transistor with a signal ARFX at node 232 to transistor 202. A signal ARMWLF can be applied to input line 203 to the gate of transistor 201 arranged as an idle transistor with VNWL set at a constant value. Each of the signals can be set one of two values to set output line 230, which is a WL in the 3D DRAM device of FIG. 3, to one of two values. With the pass gate on and the idle gate off, the WL can be set to the value of ARFX. With the idle gate on and the pass gate off, the WL can be set to the value of VNWL.

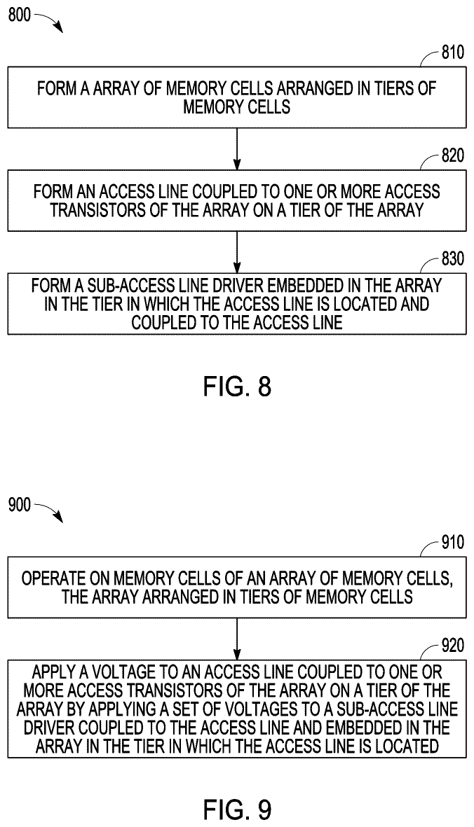

FIG. 8 is a flow diagram of features of an embodiment of an example method 800 of forming a three-dimensional memory device. For example, example method 800 can be used in forming a 3D DRAM such as, but not limited to, 3D DRAM 300 of FIG. 3. At 810, an array of memory cells, such as array 300A of 3D DRAM 300, is formed arranged in tiers of memory cells. Each memory cell can have an access transistor and a storage component. At 820, an access line, such as access line 330-1, is formed coupled to one or more access transistors of the array on a tier of the array. At X30, a sub-access line driver is formed embedded in the array in the tier in which the access line is located and coupled to the access line.

Variations of method 800 or methods similar to method 800 can include a number of different embodiments that may be combined depending on the application of such methods or the architecture or process flow of an integrated circuit for which such methods are implemented. Such methods can include forming the sub-access line driver forming a first transistor, such as transistor 301-2, coupled to the access line, such as access line 330-1, at a first end of the access line and forming a second transistor, such as transistor 301-1, coupled to the access line at a second end of the access line. The second end is opposite from the first end of the access line. The first and second transistors can be formed as n-type metal-oxide-semiconductor field-effect transistors.

Variations of method 800 or methods similar to method 800 can include forming the access line coupled to a source of the first transistor, such as transistor 301-2, and coupled to a drain of the second transistor, such as transistor 301-1. The second transistor can be formed coupled to a node, such as VNML, at which a constant voltage is operatively provided. The first transistor, such as transistor 301-2, can be formed coupled to a signal node, such as node 332-1, to operatively turn on an access transistor coupled to the access line.

Variations of method 800 or methods similar to method 800 can include forming arrays of memory cells, such as array 300A and array 300B of 3D DRAM 300, and constructing sub-access line drivers and contacts to the sub-access line drivers with forming the contacts in one of multiple arrangements. For each array, sub-access line drivers can be coupled to access lines of the array in different tiers, including forming each sub-access line driver embedded in the tier in which the access line coupled to the sub-access line driver is located. A staircase of levels, such as steps 303-1 . . . 303-8 and 304-1 . . . 304-8 of array 300A of 3D DRAM 300, can be formed arranged in a direction parallel to the access lines. Alternatively, the staircase of levels can be formed arranged in a direction perpendicular to the access lines. Rows of contacts, such as contacts 307-1 . . . 307-8 and 306-1 . . . 306-8 of array 300A of 3D DRAM 300, can be formed coupled to the sub-access line drivers that are coupled to access lines of the array in different tiers. The rows of contacts can be formed on the staircase of levels. The contacts can be formed as vertical columns with the rows formed arranged adjacent to the array of memory cells.

FIG. 9 is a flow diagram of features of an embodiment of an example method 900 of operating a three-dimensional memory device. For example, example method 900 can be used in operating 3D DRAM 300 of FIG. 3. At 910, memory cells of an array, such as array 300A of 3D DRAM 300, can be operated on. Each memory cell can have an access transistor and a storage component, with the array arranged in tiers of memory cells. The operations can include, but are not limited to, maintenance of the memory cells along with reading and writing data to the memory device. At 920, a voltage is applied to an access line, such as access line 330-1, coupled to one or more access transistors of the array on a tier of the array. A set of voltages is applied to a sub-access line driver coupled to the access line 330-1, with the sub-access line driver embedded in the array in the tier in which the access line 330-1 is located.

Variations of method 900 or methods similar to method 900 can include a number of different embodiments that may be combined depending on the application of such methods or the architecture or process flow of an integrated circuit for which such methods are implemented. Such methods can include applying the set of voltages to the sub-access line driver by applying a first voltage to a first transistor of the sub-access line driver, such as transistor 301-2, where the first transistor can be arranged as a pass gate to the access line, such as access line 330-1. A second voltage can be applied to a second transistor of the sub-access line driver, such as transistor 301-1, with the second transistor can be arranged as an idle gate to the access line, such as access line 330-1, and the first transistor and the second transistor coupled together by the access line. Variations can include setting a node, such as VNML, coupled to the second transistor, such as transistor 301-1, at a constant voltage; and applying a signal coupled to the first transistor, such as transistor 301-2, from a signal node, such as node 332-1, to operatively turn on an access transistor coupled to the access line. Variations can include applying the set of voltages to the sub-access line driver by applying the set of voltages using contacts in rows of contacts, such as contacts 307-1 . . . 307-8 and 306-1 . . . 306-8 of array 300A of 3D DRAM 300, coupled to the sub-access line driver. The contacts can be structured as vertical columns and the rows can be arranged adjacent to the array of memory cells on a staircase of levels, such as steps 303-1 . . . 303-8 and 304-1 . . . 304-8 of array 300A of 3D DRAM 300. The staircase can be arranged in a direction parallel to the access lines.

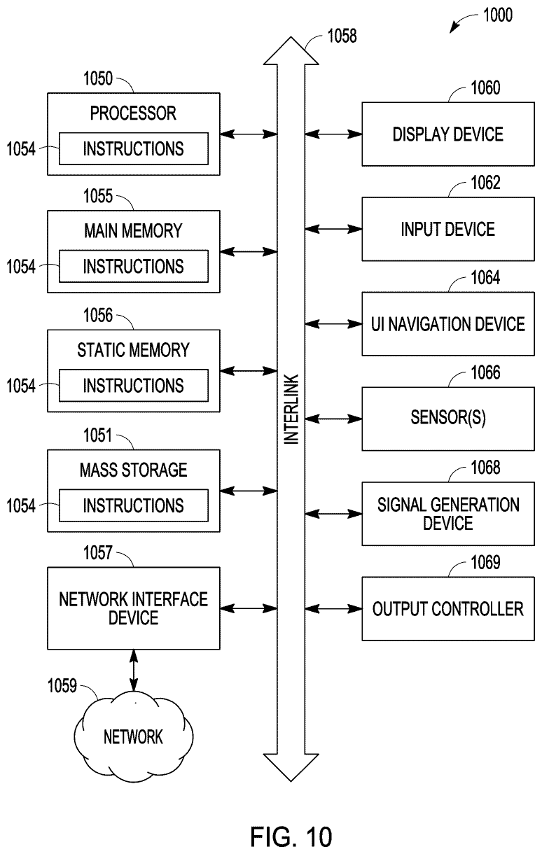

FIG. 10 illustrates a block diagram of an example machine 1000 having one or more embodiments of memory components discussed herein. In alternative embodiments, machine 1000 may operate as a standalone device or may be connected (e.g., networked) to other machines. In a networked deployment, machine 1000 may operate in the capacity of a server machine, a client machine, or both in server-client network environments. In an example, machine 1000 may act as a peer machine in peer-to-peer (P2P) (or other distributed) network environment. Machine 1000 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), other computer cluster configuration services, or controlling machine actions using stored instructions or data. Example machine 1000 can include one or more 3D memory devices with sub-access line drivers to access lines embedded in a memory array of the 3D memory devices similar to the features as discussed with respect to DRAM device 300 of FIG. 3.

Machine (e.g., computer system) 1000 may include a hardware processor 1050 (e.g., a CPU, a GPU, a hardware processor core, or any combination thereof), a main memory 1055 and a static memory 1056, some or all of which may communicate with each other via an interlink (e.g., bus) 1058. Machine 1000 may further include a display device 1060, an alphanumeric input device 1062 (e.g., a keyboard), and a user interface (UI) navigation device 1064 (e.g., a mouse). In an example, display device 1060, alphanumeric input device 1062, and UI navigation device 1064 may be a touch screen display. Machine 1000 may additionally include a mass storage (e.g., drive unit) 1051, a signal generation device 1068 (e.g., a speaker), a network interface device 1057, and one or more sensors 1066, such as a global positioning system (GPS) sensor, compass, accelerometer, or other sensor. Machine 1000 may include an output controller 1069, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 1000 may include a machine-readable medium on which is stored one or more sets of data structures or instructions 1054 (for example, software or microcode) embodying or utilized by machine 1000. Instructions 1054 may also reside, completely or at least partially, within main memory 1055, within static memory 1056, within mass storage 1051, or within hardware processor 1050 during execution thereof by machine 1000. In an example, one or any combination of hardware processor 1050, main memory 1055, static memory 1056, or mass storage 1051 may constitute machine-readable medium. Machine-readable medium can be a single medium or multiple media (e.g., a centralized or distributed database, or associated caches and servers) configured to store one or more instructions 1054.

The term “machine-readable medium” may include any medium that is capable of storing instructions for execution by machine 1000 and that cause machine 1000 to perform any one or more of the techniques for which machine 1000 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include (RAM), DRAM, SRAM, or SDRAM.

Instructions 1054 (e.g., software, programs, microcode, an operating system (OS), etc.) or other data stored on mass storage 1051 can be accessed by main memory 1055 for use by processor 1050. Main memory 1055 (e.g., DRAM) is typically fast, but volatile, and thus a different type of storage than mass storage 1051 (e.g., an SSD), which is suitable for long-term storage, including while in an “off” condition. Instructions 1054 or data in use by a user or machine 1000 are typically loaded in main memory 1055 for use by processor 1050. When main memory 1055 is full, virtual space from mass storage 1051 can be allocated to supplement main memory 1055; however, because mass storage 1051 is typically slower than main memory 1055, and write speeds are typically at least twice as slow as read speeds, use of virtual memory can greatly reduce user experience due to storage device latency (in contrast to main memory 1055, e.g., DRAM). Further, use of mass storage 1051 for virtual memory can greatly reduce the usable lifespan of mass storage 1051.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 1054 may further be transmitted or received over a network 1059 using a transmission medium via network interface device 1057 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 1057 may include one or more physical jacks (e.g., Ethernet, coaxial, or phone jacks) or one or more antennas to connect to the communications network 1026. In an example, network interface device 1057 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 1000 or data to or from machine 1000. The transportation can include using digital or analog communications signals that can be transmitted over the transmission medium to facilitate communication of such software or data.

The following are example embodiments of devices and methods, in accordance with the teachings herein.

An example three-dimensional memory device 1 can comprise an array of memory cells, where each memory cell has an access transistor and a storage component. The array is arranged in tiers of memory cells. An access line can be coupled to one or more access transistors of the array on a tier of the array. A sub-access line driver can be coupled to the access line and embedded in the array in the tier in which the access line is located.

An example three-dimensional memory device 2 can include features of example three-dimensional memory device 1 and can include the sub-access line driver having a first transistor coupled to the access line at a first end of the access line; and a second transistor coupled to the access line at a second end of the access line, where the second end is opposite the first end.

An example three-dimensional memory device 3 can include features of example three-dimensional memory device 2 and any of the preceding example three-dimensional memory devices and can include the access line being coupled to a source of the first transistor and is coupled to a drain of the second transistor.

An example three-dimensional memory device 4 can include features of example three-dimensional memory device 2 and any of the preceding example three-dimensional memory devices and can include the second transistor being coupled to a node at which a constant voltage is operatively provided and the first transistor being coupled to a signal node to operatively turn on an access transistor coupled to the access line.

An example three-dimensional memory device 5 can include features of example three-dimensional memory device 2 and any of the preceding example three-dimensional memory devices and can include the first transistor being arranged as a pass gate to the access line and the second transistor being arranged as an idle gate to the access line.

An example three-dimensional memory device 6 can include features of example three-dimensional memory device 2 and any of the preceding example three-dimensional memory devices and can include the first transistor and the second transistor being n-type metal-oxide-semiconductor field-effect transistors.

An example three-dimensional memory device 7 can include features of example three-dimensional memory device 2 and any of the preceding example three-dimensional memory devices and can include the first transistor and the second transistor being thin film transistors.

An example three-dimensional memory device 8 can include features of any of the preceding example three-dimensional memory devices and can include arrays of memory cells. For each array, rows of contacts can be coupled to sub-access line drivers that are coupled to access lines of the array in different tiers, the contacts being vertical columns and the rows of contacts arranged adjacent the array of memory cells on a staircase of levels, the staircase arranged in a direction parallel to the access lines.

An example three-dimensional memory device 9 can include features of any of the preceding example three-dimensional memory devices and can include arrays of memory cells and, for each array, rows of contacts coupled to sub-access line drivers that are coupled to access lines of the array in different tiers, the contacts being vertical columns and the rows arranged adjacent the array of memory cells on a staircase of levels, the staircase arranged in a direction perpendicular to the access lines.

An example three-dimensional memory device 10 can include features of any of the preceding example three-dimensional memory devices and can include vertically arranged local digit lines to the memory cells of the array, with access lines to tiers of memory cells arranged horizontally, the vertically arranged local digit lines disposed within a volume of the array.

In an example three-dimensional memory device 11, any of the three-dimensional memory devices of example three-dimensional memory devices 1 to 10 may include three-dimensional memory devices incorporated into an electronic apparatus further comprising a host processor or memory controller and a communication bus extending between the host processor/memory controller and the three-dimensional memory device.

In an example three-dimensional memory device 12, any of the three-dimensional memory devices of example three-dimensional memory devices 1 to 11 may be modified to include any structure presented in another of example three-dimensional memory device 1 to 11.

In an example three-dimensional memory device 13, any apparatus associated with the three-dimensional memory devices of example three-dimensional memory devices 1 to 12 may further include a machine-readable storage device configured to store instructions as a physical state, wherein the instructions may be used to perform one or more operations of the apparatus.

In an example three-dimensional memory device 14, any of the three-dimensional memory devices of example three-dimensional memory devices 1 to 13 may be operated in accordance with any of the below example methods of forming a three-dimensional memory device 1 to 10 and methods of operating a memory device 1 to 8.

An example method 1 of forming a three-dimensional memory device can comprise forming an array of memory cells arranged in tiers of memory cells with each memory cell having an access transistor and a storage component; forming an access line coupled to one or more access transistors of the array on a tier of the array; and forming a sub-access line driver embedded in the array in the tier in which the access line is located and coupled to the access line.

An example method 2 of forming a three-dimensional memory device can include features of example method 1 of forming a three-dimensional memory device and can include forming a first transistor coupled to the access line at a first end of the access line; and forming a second transistor coupled to the access line at a second end of the access line, the second end opposite the first end.

An example method 3 of forming a three-dimensional memory device can include features of example method 2 of forming a three-dimensional memory device and any of the preceding example methods of forming a three-dimensional memory device and can include forming the first and second transistors as n-type metal-oxide-semiconductor field-effect transistors.

An example method 4 of forming a three-dimensional memory device can include features of example method 2 of forming a three-dimensional memory device and any of the preceding example methods of forming a three-dimensional memory device and can include and can include forming the access line coupled to a source of the first transistor and coupled to a drain of the second transistor; forming the second transistor coupled to a node at which a constant voltage is operatively provided; and forming the first transistor coupled to a signal node to operatively turn on an access transistor coupled to the access line.

An example method 5 of forming a three-dimensional memory device can include features of any of the preceding example methods of forming a three-dimensional memory device and can include forming arrays of memory cells; and, for each array: forming sub-access line drivers coupled to access lines of the array in different tiers, including forming each sub-access line driver embedded in the tier in which the access line coupled to the sub-access line driver is located; forming a staircase of levels arranged in a direction parallel to the access lines; and forming rows of contacts coupled to the sub-access line drivers that are coupled to access lines of the array in different tiers and forming the rows of contacts on the staircase of levels, including forming the contacts as vertical columns and forming the rows arranged adjacent the array of memory cells.

An example method 6 of forming a three-dimensional memory device can include features of any of the preceding example methods of forming a three-dimensional memory device and can include forming arrays of memory cells; and, for each array: forming sub-access line drivers coupled to access lines of the array in different tiers, including forming each sub-access line driver embedded in the tier in which the access line coupled to the sub-access line driver is located; forming a staircase of levels, the staircase arranged in a direction perpendicular to the access lines; and forming rows of contacts coupled to the sub-access line drivers that are coupled to access lines of the array in different tiers and forming the rows of contacts on the staircase of levels, including forming the contacts as vertical columns and forming the rows arranged adjacent the array of memory cells.

In an example method 7, any of the example methods 1 to 6 of forming a three-dimensional memory device may be performed in forming an electronic apparatus further comprising a host processor and a communication bus extending between the host processor and a memory system.

In an example method 8 of forming a three-dimensional memory device, any of the example methods 1 to 7 of forming a three-dimensional memory device may be modified to include operations set forth in any other of example methods 1 to 7 of forming a three-dimensional memory device.

In an example method 9 of forming a three-dimensional memory device, any of the example methods 1 to 8 of forming a three-dimensional memory device may be implemented at least in part through use of instructions stored as a physical state in one or more machine-readable storage devices.

An example method 10 of forming a three-dimensional memory device can include features of any of the preceding example methods 1 to 9 of forming a three-dimensional memory device and can include performing functions associated with any features of example three-dimensional memory devices 1 to 14 and any features of example methods 1 to 8 of operating a three-dimensional memory device.

An example method 1 of operating a three-dimensional memory device can comprise operating on memory cells of an array of memory cells, each memory cell having an access transistor and a storage component, the array arranged in tiers of memory cells; and applying a voltage to an access line coupled to one or more access transistors of the array on a tier of the array by applying a set of voltages to a sub-access line driver coupled to the access line and embedded in the array in the tier in which the access line is located.

An example method 2 of operating a three-dimensional memory device can include features of example method 1 of operating a three-dimensional memory device and can include applying a first voltage to a first transistor of the sub-access line driver, the first transistor arranged as a pass gate to the access line; and applying a second voltage to a second transistor of the sub-access line driver, the second transistor arranged as an idle gate to the access line, the first transistor and the second transistor coupled together by the access line.

An example method 3 of operating a three-dimensional memory device can include features of any of the preceding example methods of operating a three-dimensional memory device and can include setting a node coupled to the second transistor at a constant voltage; and applying a signal coupled to the first transistor from a signal node to operatively turn on an access transistor coupled to the access line.

An example method 4 of operating a three-dimensional memory device can include features of any of the preceding example methods of operating a three-dimensional memory device and can include applying the set of voltages to a sub-access line driver includes applying the set of voltages using contacts in rows of contacts coupled to the sub-access line driver with the contacts structured as vertical columns and the rows arranged adjacent the array of memory cells on a staircase of levels, the staircase arranged in a direction parallel to the access lines.

In an example method 5 of operating a three-dimensional memory device, any of the example methods 1 to 4 of operating a three-dimensional memory device may be performed in forming an electronic apparatus further comprising a host processor and a communication bus extending between the host processor and a memory system.

In an example method 6 of operating a three-dimensional memory device, any of the example methods 1 to 5 of operating a three-dimensional memory device may be modified to include operations set forth in any other of example methods 1 to 5 of operating a three-dimensional memory device.

In an example method 7 of operating a three-dimensional memory device, any of the example methods 1 to 6 of operating a three-dimensional memory device may be implemented at least in part through use of instructions stored as a physical state in one or more machine-readable storage devices.

An example method 8 of operating a three-dimensional memory device can include features of any of the preceding example methods 1 to 7 of operating a three-dimensional memory device and can include performing functions associated with any features of example memory devices 1 to 12.

An example machine-readable storage device storing instructions, that when executed by one or more processors, cause a machine to perform operations, can comprise instructions to perform functions associated with any features of example three-dimensional memory devices 1 to 14 or perform form methods associated with any features of example methods 1 to 10 of forming a three-dimensional memory device or example methods 1 to 7 of operating a three-dimensional memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A three-dimensional memory device comprising:
an array of memory cells, each memory cell having an access transistor and a storage component, the array arranged in tiers of memory cells;
an access line coupled to one or more access transistors of the array on a tier of the array;
and
a sub-access line driver coupled to the access line and embedded in the array in the tier in which the access line is located.

2. The three-dimensional memory device of claim 1, wherein the sub-access line driver includes:
a first transistor coupled to the access line at a first end of the access line; and
a second transistor coupled to the access line at a second end of the access line, the second end opposite the first end.

3. The three-dimensional memory device of claim 2, wherein the access line is coupled to a source of the first transistor and is coupled to a drain of the second transistor.

4. The three-dimensional memory device of claim 2, wherein the second transistor is coupled to a node at which a constant voltage is operatively provided and the first transistor is coupled to a signal node to operatively turn on an access transistor coupled to the access line.

5. The three-dimensional memory device of claim 2, wherein the first transistor is arranged as a pass gate to the access line and the second transistor is arranged as an idle gate to the access line.

6. The three-dimensional memory device of claim 2, wherein the first transistor and the second transistor are n-type metal-oxide-semiconductor field-effect transistors.

7. The three-dimensional memory device of claim 2, wherein the first transistor and the second transistor are thin film transistors.

8. The three-dimensional memory device of claim 1, wherein the three-dimensional memory device includes:
arrays of memory cells;
for each array, rows of contacts coupled to sub-access line drivers that are coupled to access lines of the array in different tiers, the contacts being vertical columns and the rows arranged adjacent the array of memory cells on a staircase of levels, the staircase arranged in a direction parallel to the access lines.

9. The three-dimensional memory device of claim 1, wherein the three-dimensional memory device includes:
arrays of memory cells;
for each array, rows of contacts coupled to sub-access line drivers that are coupled to access lines of the array in different tiers, the contacts being vertical columns and the rows arranged adjacent the array of memory cells on a staircase of levels, the staircase arranged in a direction perpendicular to the access lines.

10. The three-dimensional memory device of claim 1, wherein the three-dimensional memory device includes vertically arranged local digit lines to the memory cells of the array, with access lines to tiers of memory cells arranged horizontally, the vertically arranged local digit lines disposed within a volume of the array.

11. A method of forming a three-dimensional memory device, the method comprising:
forming an array of memory cells arranged in tiers of memory cells with each memory cell having an access transistor and a storage component;
forming an access line coupled to one or more access transistors of the array on a tier of the array; and
forming a sub-access line driver embedded in the array in the tier in which the access line is located and coupled to the access line.

12. The method of claim 11, wherein forming the sub-access line driver includes:
forming a first transistor coupled to the access line at a first end of the access line; and
forming a second transistor coupled to the access line at a second end of the access line, the second end opposite the first end.

13. The method of claim 12, wherein the method includes forming the first and second transistors as n-type metal-oxide-semiconductor field-effect transistors.

14. The method of claim 12, wherein the method includes:
forming the access line coupled to a source of the first transistor and coupled to a drain of the second transistor;
forming the second transistor coupled to a node at which a constant voltage is operatively provided; and
forming the first transistor coupled to a signal node to operatively turn on an access transistor coupled to the access line.

15. The method of claim 11, wherein the method includes:
forming arrays of memory cells; and
for each array:
forming sub-access line drivers coupled to access lines of the array in different tiers, including forming each sub-access line driver embedded in the tier in which the access line coupled to the sub-access line driver is located;
forming a staircase of levels arranged in a direction parallel to the access lines;
and
forming rows of contacts coupled to the sub-access line drivers that are coupled to access lines of the array in different tiers and forming the rows of contacts on the staircase of levels, including forming the contacts as vertical columns and forming the rows arranged adjacent the array of memory cells.

16. The method of claim 11, wherein the method includes:
forming arrays of memory cells; and
for each array:
forming sub-access line drivers coupled to access lines of the array in different tiers, including forming each sub-access line driver embedded in the tier in which the access line coupled to the sub-access line driver is located;
forming a staircase of levels, the staircase arranged in a direction perpendicular to the access lines; and
forming rows of contacts coupled to the sub-access line drivers that are coupled to access lines of the array in different tiers and forming the rows of contacts on the staircase of levels, including forming the contacts as vertical columns and forming the rows arranged adjacent the array of memory cells.

17. A method of operating a three-dimensional memory device comprising:
operating on memory cells of an array of memory cells, each memory cell having an access transistor and a storage component, the array arranged in tiers of memory cells; and
applying a voltage to an access line coupled to one or more access transistors of the array on a tier of the array by applying a set of voltages to a sub-access line driver coupled to the access line and embedded in the array in the tier in which the access line is located.

18. The method of claim 17, wherein applying the set of voltages to the sub-access line driver includes:
applying a first voltage to a first transistor of the sub-access line driver, the first transistor arranged as a pass gate to the access line; and
applying a second voltage to a second transistor of the sub-access line driver, the second transistor arranged as an idle gate to the access line, the first transistor and the second transistor coupled together by the access line.

19. The method of claim 18, wherein the method includes:
setting a node coupled to the second transistor at a constant voltage; and
applying a signal coupled to the first transistor from a signal node to operatively turn on an access transistor coupled to the access line.

20. The method of claim 17, wherein applying the set of voltages to a sub-access line driver includes applying the set of voltages using contacts in rows of contacts coupled to the sub-access line driver with the contacts structured as vertical columns and the rows arranged adjacent the array of memory cells on a staircase of levels, the staircase arranged in a direction parallel to the access lines.
